(19) United States
(12) Patent Application Publication
(10) Pub. No.: US 2020/0025641 A1
(43) Pub. Date: Jan. 23, 2020

(54) LEAK-DETACHABLE LIQUID-HEAT-TRANSMISSION DEVICE

(71) Applicants: Ling LONG, Shanghai (CN); Haixia WANG, Shanghai (CN); Tonghu XIA, Shanghai (CN); Shanghai LuYao Energy Technology Co., Ltd., Shanghai (CN)

(72) Inventors: Ling LONG, Shanghai (CN); Haixia WANG, Shanghai (CN); Tonghu XIA, Shanghai (CN)

(21) Appl. No.: 16/039,298

(22) Filed: Jul. 18, 2018

(51) Int. Cl. G01M 3/16; F28F 27/02

(52) U.S. Cl. CPC G01M 3/16; H05K 7/20218; F28F 27/02

(57) ABSTRACT

A leak-detectable liquid-heat-transmission device including a heat conductive plate, a cover covering on one surface of the heat conductive plate, and a channel structure disposed in the cover is provided. The channel structure is arranged on the heat conductive plate and the cover. A flow chamber and a leak detecting channel surrounding and isolated from the flow chamber is defined between the cover and the heat conductive plate by the channel structure. An inlet and an outlet respectively communicated with the flow chamber are defined on the cover, and a fluid sensor for detecting the working fluid leaking from the flow chamber is arranged in the leak detecting channel.

### FIELD OF THE INVENTION

This disclosure relates to a liquid-heat-transmission device applied to liquid-cooling systems and more particularly to a leak-detectable liquid-heat-transmission device capable of detecting any leakage of a coolant.

### BACKGROUND OF THE INVENTION

In general, a large amount of heat is generated during an operation of a high-performance electronic device, and the heat generated by the high-performance electronic device cannot be eliminated timely by just using a fan, so that a liquid-cooled heat sink is usually installed to the high-performance electronic device. A conventional liquid-cooled heat sink generally includes a water cooling head and a circulation pipeline communicated to the water cooling head, and the circulation pipeline is filled with a working fluid, and the water cooling head is contacted with a heat source in the electronic device, and the working fluid passes through the heat source of the water cooling head to perform a heat exchange in order to remove the heat generated by the heat source. Although the liquid-cooled heat sink has good heat exchange efficiency, the liquid-cooled heat sink still has a major drawback which is the leaking of the working fluid. Since the water cooling head is in direct contact with the heat source (or the electronic component), the working fluid may overflow to the electronic components of the electronic device or damage the electronic device during the leakage of the working fluid.

In view of the aforementioned drawback of the prior art, the discloser of this disclosure based on years of experience to conduct extensive research and experiment, and finally provided a feasible solution to overcome the drawbacks of the prior art.

### SUMMARY OF THE INVENTION

Therefore, it is a primary objective of this disclosure to provide a leak-detectable liquid-heat-transmission device capable of detecting a leak of a coolant.

To achieve the aforementioned and other objectives, this disclosure provides a leak-detectable liquid-heat-transmission device comprising a heat conductive plate, a cover covering one of the sides of the heat conductive plate, and a channel structure disposed in the cover, wherein the channel structure has a flow chamber formed and enclosed between the heat conductive plate and the cover, and surrounding the flow chamber, and a leak detecting channel separated from the flow chamber, and the cover has an inlet and an outlet formed on the cover and communicated to the flow chamber, and the leak detecting channel has a fluid sensor installed therein.

In the leak-detectable liquid-heat-transmission device of this disclosure, the channel structure comprises a plurality of fins arranged with an interval apart from one another and disposed inside the flow chamber and between the inlet and the outlet, and each of the fins is extended longitudinally along a surface of the heat conductive plate, and each of the fins is coupled to the heat conductive plate and the cover. Each of the fins is formed and protruded from a surface of the heat conductive plate and transversely protruded to touch the cover, or each of the fins is formed and protruded from an inner surface of the cover and transversely projected to touch the heat conductive plate.

The leak-detectable liquid-heat-transmission device of this disclosure further comprises an inner sealing ring clamped between the heat conductive plate and the channel structure, and the inner sealing ring surrounds the flow chamber, and the leak detecting channel surrounds the inner sealing ring, or the leak-detectable liquid-heat-transmission device of this disclosure further comprises an inner sealing ring clamped between the cover and the channel structure, and the inner sealing ring surrounding the flow chamber, and the leak detecting channel surrounding the inner sealing ring. The channel structure comprises a surrounding wall surrounding the flow chamber, and a trench is formed at the top edge of the surrounding wall, and the inner sealing ring is embedded in the trench.

The leak-detectable liquid-heat-transmission device of this disclosure further comprises a trench formed at the outer periphery of the cover, and the trench surrounds the leak detecting channel, and the trench has an outer sealing ring embedded therein, and the outer sealing ring is clamped between the heat conductive plate and the cover.

In the liquid-heat-transmission device of this disclosure, the cover has a leak detecting channel installed in the channel structure, so that when there is a leakage of the working fluid flowing along the channel structure occurred between the heat conductive plate and the cover, the fluid sensor in the leak detecting channel is capable of detecting the working fluid that leaks from the flow chamber and sends out a corresponding signal to take a corresponding action.

### BRIEF DESCRIPTION OF THE DRAWINGS

FIGS. 1 to 3 are schematic views of a leak-detectable liquid-heat-transmission device in accordance with a first embodiment of this disclosure; and

FIGS. 4 to 6 are schematic views of a leak-detectable liquid-heat-transmission device in accordance with a second embodiment of this disclosure.

### DESCRIPTION OF THE PREFERRED EMBODIMENTS

The technical contents of this disclosure will become apparent with the detailed description of preferred embodiments accompanied with the illustration of related drawings as follows. It is intended that the embodiments and figures disclosed herein are to be considered illustrative rather than restrictive.

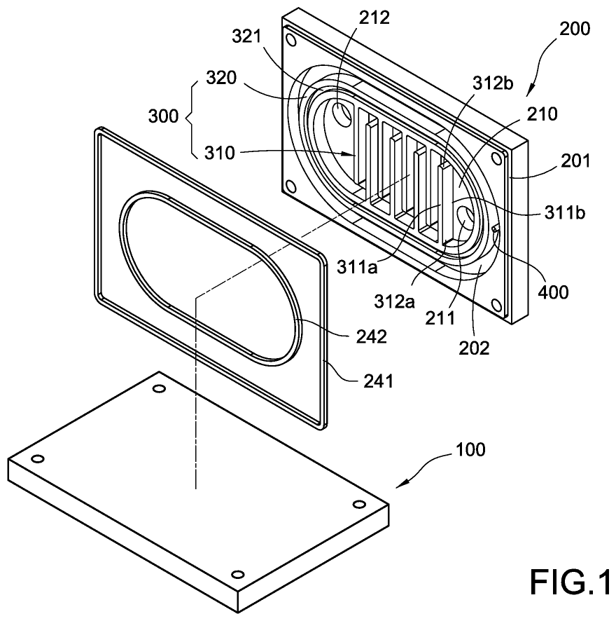

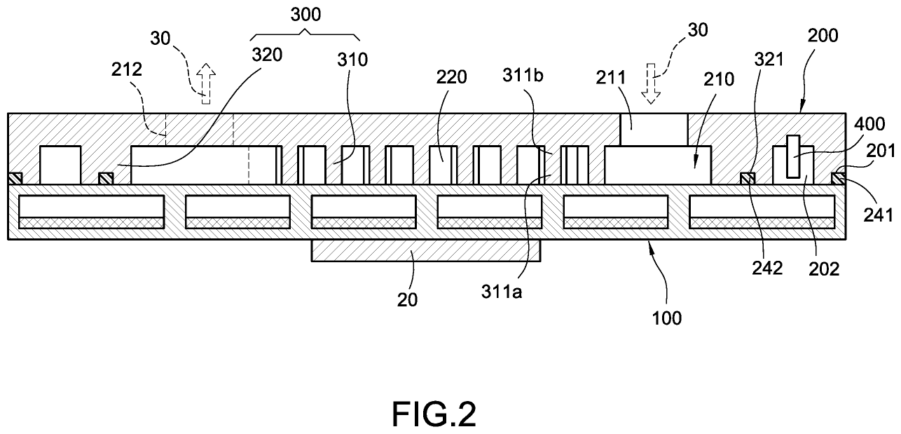

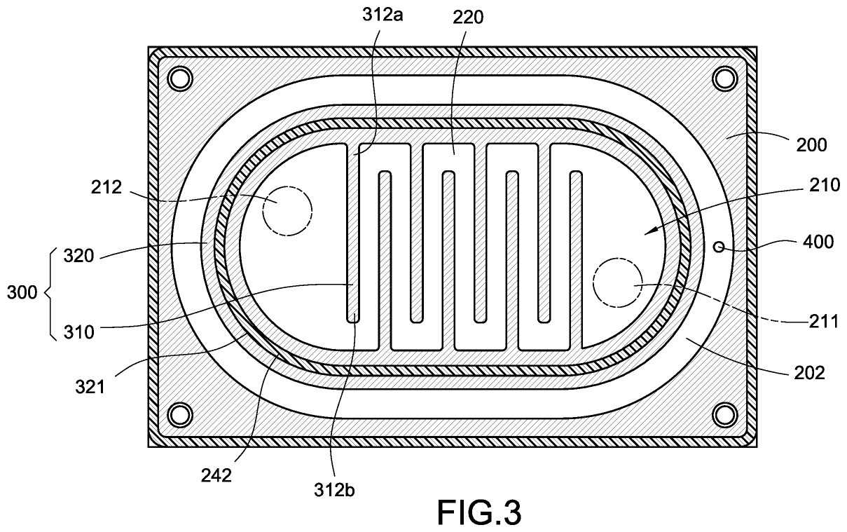

With reference to FIGS. 1 to 3 for a liquid-heat-transmission device in accordance with the first embodiment of this disclosure, the liquid-heat-transmission device comprises a heat conductive plate 100, a cover 200, and a channel structure 300.

In the liquid-heat-transmission device of this embodiment of the present disclosure, the cover 200 is covered onto a side of the heat conductive plate 100 outputting heat energy, and a trench 201 is formed at the outer periphery of the cover 200 and surrounds a flow chamber 210, and an outer sealing ring 241 is embedded into the trench 201 and clamped between the heat conductive plate 100 and the cover 200 to seal the heat conductive plate 100 and the cover 200.

The channel structure 300 is installed in the cover 200 and provided for forming and enclosing a flow chamber 210 and a leak detecting channel 202 between the heat conductive plate 100 and the cover 200, and the leak detecting channel 202 is surrounded around the flow chamber 210 and separated from the flow chamber 210. However, this disclosure is not just limited to such arrangement only, but the channel structure 300 may also comprises a plurality of leak detecting channels 202 arranged around the flow chamber 210. The flow chamber 210 is provided for allowing a working fluid 30 (which may be water or any other liquid or gas) to pass through and exchange heat with a side of the heat conductive plate 100 that outputs heat energy.

The cover 200 has an inlet 211 and an outlet 212 formed thereon and communicated with the flow chamber 210 for flowing the working fluid 30 into the flow chamber 210 and out from the flow chamber 210 respectively. After the working fluid 30 passes through the outlet 212 and flows out from the flow chamber 210, the working fluid 30 may be cooled before passing through the inlet 211 and circulating into the flow chamber 210 again. However, this disclosure is not limited to such arrangement only. The working fluid 30 may not be recirculated, but it is directly discharged to the outside after passing through the outlet 212 and flowing out from the flow chamber 210.

In this embodiment, the channel structure 300 comprises a plurality of fins 310 arranged with an interval apart from one another, and a surrounding wall 320 surrounding the plurality of fins 310. The fins 310 are arranged between the inlet 211 and the outlet 212, and each fin 310 is extended longitudinally along a surface of the heat conductive plate 100. In this embodiment, each fin 310 preferably has a pair of side edges 311a/311b configured to be opposite to each other and coupled to the heat conductive plate 100 and the cover 200, and each fin 310 is preferably formed and protruded from an inner surface of the cover 200 and transversely projected to touch the heat conductive plate 100, so that the side edges 311a/311b are coupled to the heat conductive plate 100 and the cover 200 respectively.

In this embodiment, an inner sealing ring 242 is clamped between the heat conductive plate 100 and the channel structure 300, and the inner sealing ring 242 surrounds the flow chamber 210, and the leak detecting channel 202 surrounds the inner sealing ring 242, so as to seal and separate the leak detecting channel 202 and the flow chamber 210. The surrounding wall 320 preferably has a trench 321 formed at the top edge of the surrounding wall 320, and the inner sealing ring 242 is embedded into the trench 321 and clamped between heat conductive plate 100 and the channel structure 300.

In this embodiment, both ends of each fin 310 are coupled to a connecting end 312a and a separating end 312b of an inner wall of the cover 200 respectively, wherein the connecting end 312a and separating end 312b are separated from each other. The connecting ends 312a and separating ends 312b of the fins 310 are arranged interspersely, so that the fins 310 have a single flow channel 220 formed at the internal periphery of the flow chamber 210 and communicated between the inlet 211 and the outlet 212 and extended along a surface of the heat conductive plate 100 in a roundabout manner.

The working fluid 30 passes through the inlet 211 and enters into the flow chamber 210, and then the working fluid 30 flows along the channel structure 300 and passes through the flow chamber 210, and then the working fluid 30 passes through the single flow channel 220 and flows through a surface of the heat conductive plate 100 is a roundabout manner to carry out the heat exchange and fully absorb the heat energy in the heat conductive plate 100, and then the working fluid 30 passes through the outlet 212 and is discharged from the flow chamber 210 to dissipate the heat from the liquid-heat-transmission device to the outside. In the liquid-heat-transmission device of this disclosure, the fins 310 are provided for guiding the working fluid 30 to flow from the inlet 211 to the outlet 212, and the working fluid 30 flows through the heat conductive plate 100 and exchanges heat with the heat conductive plate 100, so as to transfer the heat of the heat conductive plate 100 to the working fluid 30.

Once if the flow chamber 210 has a leakage (which is may be a small leakage falling within an allowable range, or an abnormal leakage) or its sealed status is destructed, then the working fluid 30 will infiltrate into the leak detecting channel 202, but the outer sealing ring 241 still can prevent the working fluid 30 from passing between the heat conductive plate 100 and the cover 200 or infiltrating out of the liquid-heat-transmission device. The leak detecting channel 202 has at least a fluid sensor 400 installed therein, and the fluid sensor 400 in the leak detecting channel 202 can detect the working fluid 30 and transmit a corresponding signal for taking a corresponding action (such as driving an indicating lamp to light up or disconnecting a pump for pumping the working fluid 30). In this embodiment, each fluid sensor 400 preferably transmits signals through a conductive wire. However, this disclosure is not limited to such arrangement only, and each fluid sensor 400 may also transmit signals via a wireless transmission. In this embodiment, the leak detecting channel 202 preferably has a plurality of fluid sensors 400 installed on different sides of the flow chamber 210 in order to detect the sealed status of each side of the flow chamber 210.

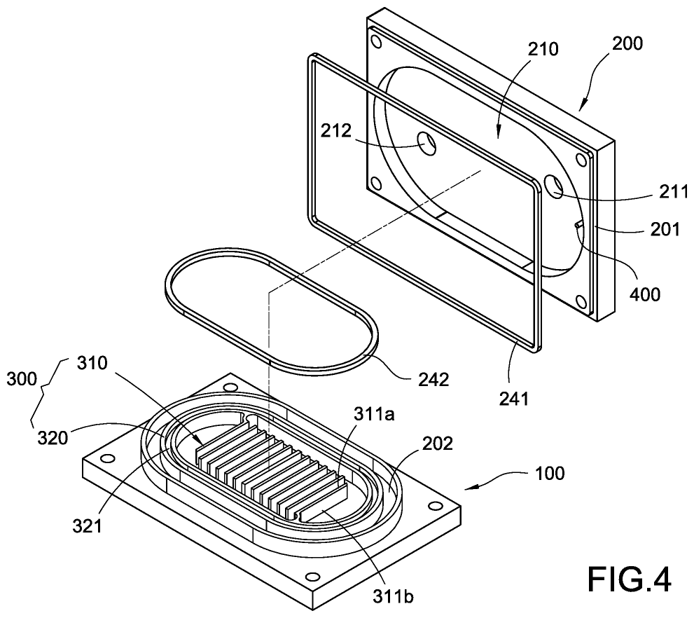

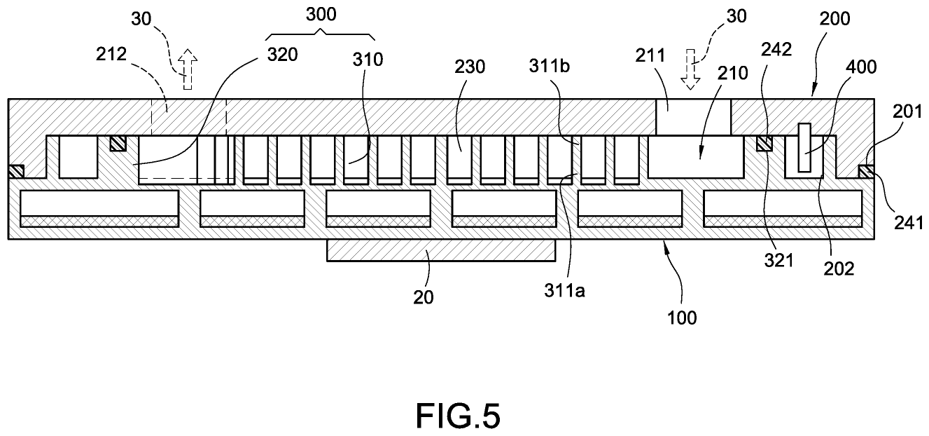

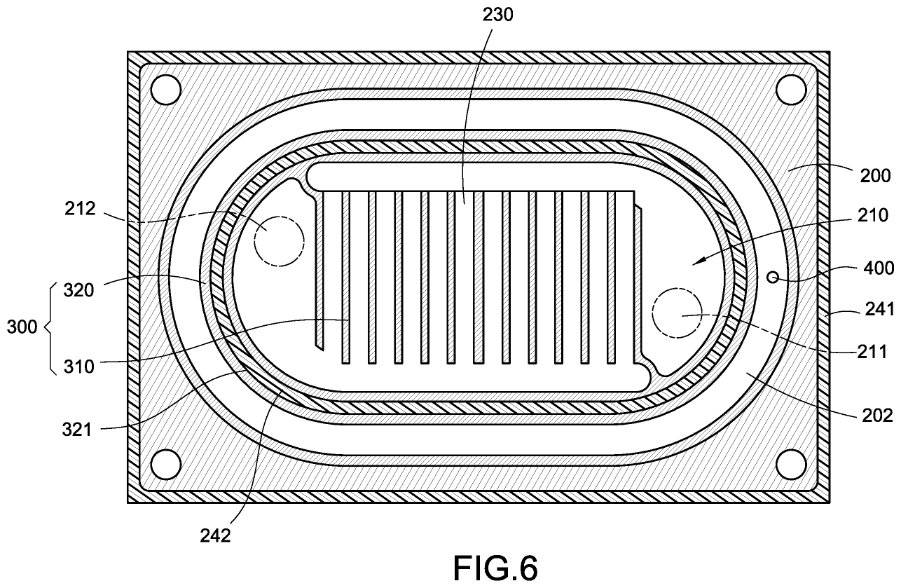

With reference to FIGS. 4 to 6 for a liquid-heat-transmission device in accordance with the second embodiment of this disclosure, the liquid-heat-transmission device comprises a heat conductive plate 100, a cover 200, and a channel structure 300. The cover 200 covers a side of the heat conductive plate 100 that outputs heat energy, and the channel structure 300 is installed in the cover 200, and a flow chamber 210 and a leak detecting channel 202 is formed between the heat conductive plate 100 and the cover 200 by the channel structure 300, and the leak detecting channel 202 surrounds the flow chamber 210 and is separated from the flow chamber 210. The flow chamber 210 is provided for a working fluid 30 (which may be water or any other liquid) to pass through and exchange heat with a side of the heat conductive plate 100 that outputs heat energy. The cover 200 has an inlet 211 and an outlet 212 formed thereon and communicated to the flow chamber 210 for flowing the working fluid 30 into the flow chamber 210 and out from the flow chamber 210 respectively.

The structure of this embodiment is substantially the same as that of the first embodiment, and their difference resides on that each fin 30 of this embodiment formed and protruded from a surface of the heat conductive plate 100 and transversely projected to touch the cover 200, and each fin 310 is extended longitudinally along a surface of the heat conductive plate 100, and both sides of each fin 310 are separated from the inner wall of the cover 200. The channel structure 300 further comprises a surrounding wall 320 surrounding the fins 310, and the surrounding wall 320 separates and divides the interior of the cover 200 into a flow chamber 210 and leak detecting channel 202, The fins 310 form a plurality of shunt channels 230 at the internal periphery of the flow chamber 210 and communicated between the inlet 211 and the outlet 212. In this embodiment, the inner sealing ring 242 is clamped between the surrounding wall 320 and the cover 200. A trench 321 is preferably formed at the top edge of the surrounding wall 320 and the inner sealing ring 242 is embedded into the trench 321 and clamped between the heat conductive plate 100 and the channel structure 300.

The working fluid 30 passes through the inlet 211 and enters into the flow chamber 210, and then passes through each shunt channel 230 and flows through a surface of the heat conductive plate 100 to fully absorb the heat in the heat conductive plate 100, and then the working fluid 30 passes through the outlet 212 and is discharged from the flow chamber 210 to dissipate the heat to the outside from the liquid-heat-transmission device. Once if the flow chamber 210 has a leakage, the fluid sensor 400 in the leak detecting channel 202 is capable of detecting any working fluid 30 leaking out from the flow chamber 210 and transmitting a corresponding signal provided for taking a corresponding action.

While this disclosure has been described by means of specific embodiments, numerous modifications and variations could be made thereto by those skilled in the art without departing from the scope and spirit of this disclosure set forth in the claims.

What is claimed is:

1. A leak-detectable liquid-heat-transmission device, comprising a heat conductive plate, a cover covering one of sides of the heat conductive plate, and a channel structure disposed in the cover, and the channel structure having a flow chamber formed and enclosed between the heat conductive plate and the cover, surrounding the flow chamber, and a leak detecting channel separated from the flow chamber, and the cover having an inlet and an outlet formed on the cover and communicated to the flow chamber, and the leak detecting channel having a fluid sensor installed therein.

2. The leak-detectable liquid-heat-transmission device of claim 1, wherein the channel structure comprises a plurality of fins arranged with an interval apart from one another and disposed inside the flow chamber and between the inlet and the outlet, and each of the fins is extended longitudinally along a surface of the heat conductive plate, and each of the fins is coupled to the heat conductive plate and the cover.

3. The leak-detectable liquid-heat-transmission device of claim 2, wherein each of the fins is formed and protruded from a surface of the heat conductive plate and transversely protruding to touch the cover.

4. The leak-detectable liquid-heat-transmission device of claim 2, wherein each of the fins is formed and protruded from an inner surface of the cover and transversely projected to touch the heat conductive plate.

5. The leak-detectable liquid-heat-transmission device of claim 1, further comprising an inner sealing ring clamped between the heat conductive plate and the channel structure, and the inner sealing ring surrounding the flow chamber, and the leak detecting channel surrounding the inner sealing ring.

6. The leak-detectable liquid-heat-transmission device of claim 1, further comprising an inner sealing ring clamped between the cover and the channel structure, and the inner sealing ring surrounding the flow chamber, and the leak detecting channel surrounding the inner sealing ring.

7. The leak-detectable liquid-heat-transmission device of claim 5, wherein the channel structure comprises a surrounding wall surrounding the flow chamber, and a trench is formed at the top edge of the surrounding wall, and the inner sealing ring is embedded in the trench.

8. The leak-detectable liquid-heat-transmission device of claim 6, wherein the channel structure comprises a surrounding wall surrounding the flow chamber, and a trench is formed at the top edge of the surrounding wall, and the inner sealing ring is embedded into the trench.

9. The leak-detectable liquid-heat-transmission device of claim 1, further comprising a trench formed at the outer periphery of the cover, and the trench surrounding the leak detecting channel, and the trench having an outer sealing ring embedded therein, and the outer sealing ring being clamped between the heat conductive plate and the cover.
